(19) United States
(12) Patent Application Publication
(10) Pub. No.: US 2026/0305200 A1
(43) Pub. Date: Oct. 1, 2026

(54) METHOD OF MANUFACTURING SEMICONDUCTOR DEVICE

(71) Applicant: FUJI ELECTRIC CO., LTD., Kawasaki-shi (JP)

(72) Inventor: Ryosuke KAMAKURA, Matsumoto-city (JP)

(73) Assignee: FUJI ELECTRIC CO., LTD., Kawasaki-shi (JP)

(21) Appl. No.: 19/552,386

(22) Filed: Feb. 27, 2026

(30) Foreign Application Priority Data
Mar. 28, 2025 (JP) 2025-057268

(51) Int. Cl. H10P 30/20; H10D 64/01; H10W 20/00

(52) U.S. Cl. CPC H10P 30/21; H10D 64/0111; H10W 20/056

(57) ABSTRACT

A method of manufacturing a semiconductor device, including: preparing a semiconductor substrate having a single crystal silicon region, and a polycrystalline silicon region; forming an interlayer insulating film covering the single and polycrystalline silicon regions; forming in the interlayer insulating film, a plurality of first contact holes exposing the single crystal silicon region and a second contact hole exposing the polycrystalline silicon region; performing an ion implantation in the single crystal silicon region exposed by the first contact holes; etching the single and polycrystalline silicon regions, thereby concurrently forming a plurality of first contact trenches and a second contact trench respectively continuous with the plurality of first contact holes and the second contact hole; and forming a first electrode and a second electrode respectively electrically connected to the single crystal silicon region in the first contact trenches and the polycrystalline silicon region in the second contact trench.

### CROSS REFERENCE TO RELATED APPLICATIONS

This application is based upon and claims the benefit of priority of the prior Japanese Patent Application No. 2025-057268, filed on Mar. 28, 2025, the entire contents of which are incorporated herein by reference.

### BACKGROUND OF THE INVENTION

### 1. Field of the Invention

Embodiments of the disclosure relate to a method of manufacturing a semiconductor device.

### 2. Description of the Related Art

Japanese Laid-Open Patent Publication No. 2001-007337 describes a technique of eliminating an etching rate difference between through-oxide films due to ion implantation damage by removing the through-oxide film by wet etching and thereby preventing loss of a LOCOS film below the through-oxide film. Japanese Laid-Open Patent Publication No. 2003-179031 describes a technique of replacing a portion of an Al layer and a portion of a natural oxide film at a surface of an Si amorphous layer on the Al layer with a chemically stable oxide layer by implantation of metal ions and sputtering, and removing a portion other than the oxide layer by dry etching one atomic layer at a time.

### SUMMARY OF THE INVENTION

According to an embodiment of the present disclosure, a method of manufacturing a semiconductor device, the method including: preparing a semiconductor substrate having a main surface, a single crystal silicon region formed in the semiconductor substrate, and a polycrystalline silicon region formed on the semiconductor substrate at the main surface; as a first process, forming an interlayer insulating film covering the single crystal silicon region and the polycrystalline silicon region; as a second process, forming in the interlayer insulating film, a plurality of first contact holes exposing the single crystal silicon region and a second contact hole exposing the polycrystalline silicon region; as a third process, performing an ion implantation of a dopant in the single crystal silicon region, at portions thereof exposed by the plurality of first contact holes; as a fourth process, using the interlayer insulating film as a mask and etching the single crystal silicon region and the polycrystalline silicon region, thereby concurrently forming a plurality of first contact trenches respectively continuous with the plurality of first contact holes and a second contact trench continuous with the second contact hole; as a fifth process, forming a first electrode electrically connected to the single crystal silicon region at an inner wall of each of the plurality of first contact trenches; and as a sixth process, forming a second electrode electrically connected to the polycrystalline silicon region at an inner wall of the second contact trench.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting an example of a layout when a semiconductor device manufactured according to a method of manufacturing a semiconductor device according to an embodiment is viewed from a front side of a semiconductor substrate thereof.

FIG. 2 is a cross-sectional view depicting an example of a structure along cutting line A-A′ in FIG. 1.

FIG. 3 is a cross-sectional view depicting an example of a structure along cutting line B-B′ in FIG. 1.

FIG. 4 is a flowchart depicting an outline of the method of manufacturing the semiconductor device according to the embodiment.

FIG. 5A is a cross-sectional view schematically depicting a state of the semiconductor device according to the embodiment during manufacture.

FIG. 5B is a cross-sectional view schematically depicting a state of the semiconductor device according to the embodiment during manufacture.

FIG. 6A is a cross-sectional view schematically depicting a state of the semiconductor device according to the embodiment during manufacture.

FIG. 6B is a cross-sectional view schematically depicting a state of the semiconductor device according to the embodiment during manufacture.

FIG. 7A is a cross-sectional view schematically depicting a state of the semiconductor device according to the embodiment during manufacture.

FIG. 7B is a cross-sectional view schematically depicting a state of the semiconductor device according to the embodiment during manufacture.

FIG. 8A is a cross-sectional view schematically depicting a state of the semiconductor device according to the embodiment during manufacture.

FIG. 8B is a cross-sectional view schematically depicting a state of the semiconductor device according to the embodiment during manufacture.

FIG. 9A is a cross-sectional view schematically depicting a state of the semiconductor device according to the embodiment during manufacture.

FIG. 9B is a cross-sectional view schematically depicting a state of the semiconductor device according to the embodiment during manufacture.

FIG. 10 is a characteristic diagram depicting a relationship between acceleration voltage and range (Rp-standard deviation (1σ)) of boron ions.

FIG. 11 is a characteristics diagram schematically depicting a difference in the etching rates (=the etching amount/the etching time) of the single crystal Si and poly-silicon.

FIG. 12 is a flowchart depicting an outline of a method of manufacturing a semiconductor device of a reference example.

FIG. 13A is a cross-sectional view schematically depicting a state of the semiconductor device of the reference example during manufacture.

FIG. 13B is a cross-sectional view schematically depicting a state of the semiconductor device of the reference example during manufacture.

FIG. 14A is a cross-sectional view schematically depicting a state of the semiconductor device of the reference example during manufacture.

FIG. 14B is a cross-sectional view schematically depicting a state of the semiconductor device of the reference example during manufacture.

FIG. 15A is a cross-sectional view schematically depicting a state of the semiconductor device of the reference example during manufacture.

FIG. 15B is a cross-sectional view schematically depicting a state of the semiconductor device of the reference example during manufacture.

FIG. 16A is a cross-sectional view schematically depicting a state of the semiconductor device of the reference example during manufacture.

FIG. 16B is a cross-sectional view schematically depicting a state of the semiconductor device of the reference example during manufacture.

### DETAILED DESCRIPTION OF THE INVENTION

In Japanese Laid-Open Patent Publication No. 2001-007337 and Japanese Laid-Open Patent Publication No. 2003-179031, when portions formed of differing materials (for example, a single crystal silicon portion and a gate electrode) are processed concurrently by etching, there is a large difference in the etching amounts of these portions and a portion may be excessively etched unintentionally, whereby reliability of the semiconductor device may decrease.

An outline of an embodiment of the present disclosure is described. (1) A method of manufacturing a semiconductor device according to one aspect of the present disclosure is as follows. As a first process, at a main surface of a semiconductor substrate having a single crystal silicon region and a polycrystalline silicon region, an interlayer insulating film is formed, the interlayer insulating film covering the single crystal silicon region and the polycrystalline silicon region. As a second process, in the interlayer insulating film, a plurality of first contact holes exposing the single crystal silicon region and a second contact hole exposing the polycrystalline silicon region are formed. As a third process, an ion implantation of a dopant is performed in portions of the single crystal silicon region exposed by the plurality of first contact holes. As a fourth process, the interlayer insulating film is used as a mask and the single crystal silicon region and the polycrystalline silicon region are etched, concurrently forming a plurality of first contact trenches respectively continuous with the plurality of first contact holes and a second contact trench continuous with the second contact hole. As a fifth process, a first electrode electrically connected to the single crystal silicon region at an inner wall of each of the plurality of first contact trenches is formed. As a sixth process, a second electrode electrically connected to the polycrystalline silicon region at an inner wall of the second contact trench is formed.

According to the disclosure above, the etching rate of the single crystal silicon of the portions where the plurality of first contact trenches is formed may be increased and thus, the etching rate of the single crystal silicon of the portions where the plurality of first contact trenches is formed may be brought close to the etching rate of the polycrystalline silicon region. As a result, a difference in the depth of the plurality of first contact trenches and the depth of the second contact trench may be reduced. Further, the etching rate of the single crystal silicon of the portions where the plurality of first contact trenches is formed is increased, whereby the etching time is shortened and thus, productivity may be improved.

(2) Further, in the method of manufacturing the semiconductor device according to the present disclosure, in (1) above, in the third process, a plurality of first regions that break covalent bonds of the single crystal silicon is formed in the single crystal silicon region, by the ion implantation; and in the fourth process, the plurality of first regions may be etched thereby forming the plurality of first contact trenches.

According to the disclosure above, in the plurality of first regions, the etching rate increases as the single crystal silicon is amorphized.

(3) Further, in the method of manufacturing the semiconductor device according to the present disclosure, in (2) above, in the third process, a second region is concurrently formed in the polycrystalline silicon region with the plurality of first regions, by the ion implantation; and in the fourth process, the second contact trench may be formed by etching the second region.

According to the disclosure above, when the plurality of first regions is formed, even when the second region is formed in the polycrystalline silicon region, the difference in the depth of the plurality of first contact trenches and the depth of the second contact trench may be reduced.

(4) Further, in the method of manufacturing the semiconductor device according to the present disclosure, in any one of (1) to (3) above, the semiconductor substrate is formed by the single crystal silicon region; in the first process, in a second device region apart from a first device region in which the plurality of first contact trenches is formed, the polycrystalline silicon region may be formed via an insulating layer at the main surface of the semiconductor substrate.

According to the disclosure above, the single crystal silicon region constituting the semiconductor substrate itself and the polycrystalline silicon region formed at the main surface of the semiconductor substrate are electrically isolated from each other by the insulating layer.

(5) Further, in the method of manufacturing the semiconductor device according to the present disclosure, in (4) above, in the first process, the insulating layer may be formed by thermal oxidation.

According to the disclosure above, high reliability of the insulating layer is obtained.

(6) Further, in the method of manufacturing the semiconductor device according to the present disclosure, in (4) above, in the first process, a device structure may be formed in the first device region.

According to the disclosure above, various device structures are applicable.

(7) Further, in the method of manufacturing the semiconductor device according to the present disclosure, in any one of (1) to (6) above, the dopant contains boron and in the ion implantation, monovalent or divalent boron ions may be implanted.

According to the disclosure above, the etching rate of the single crystal silicon of the portions where the plurality of first contact trenches is formed may be increased and a p⁺⁺-type region for realizing a low-resistance contact with the first electrode may be formed.

(8) Further, in the method of manufacturing the semiconductor device according to the present disclosure, in any one of (1) to (7) above, in the third process, an acceleration voltage of the ion implantation may be set so that a peak of a concentration of the dopant occurs at a depth in a range of 0.40 μm to 0.90 μm from an ion-implanted surface of the ion implantation.

According to the disclosure above, regions containing the dopant ion implanted by the third process may be left at the bottoms of the plurality of first contact trenches.

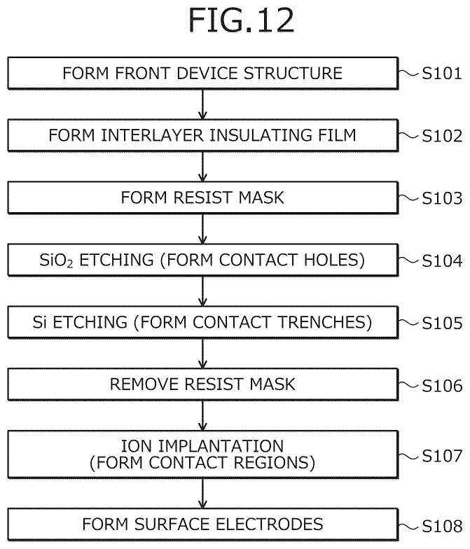

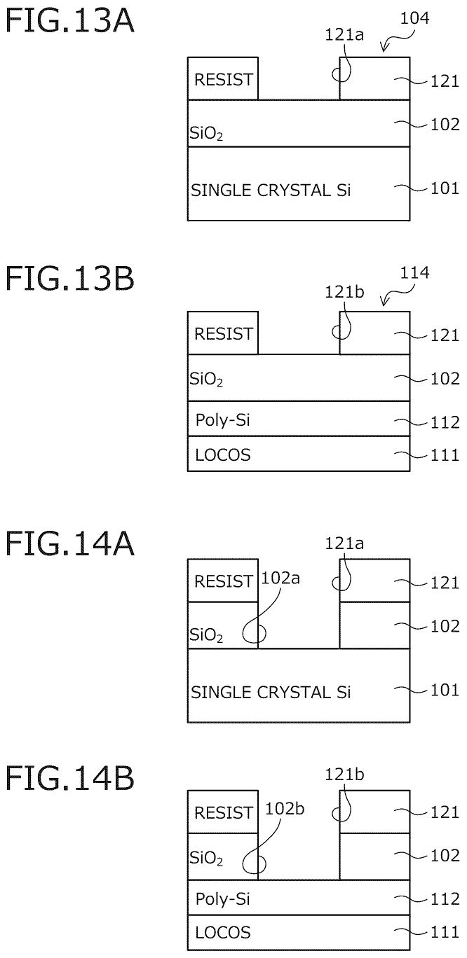

Here, findings underlying the present disclosure are discussed. A method of manufacturing a semiconductor device of a reference example is described. FIG. 12 is a flowchart depicting an outline of the method of manufacturing the semiconductor device of the reference example. FIGS. 13A, 13B, 14A, 14B, 15A, 15B, 16A, and 16B are cross-sectional views schematically depicting states of the semiconductor device of the reference example during manufacture. FIGS. 13A, 14A, 15A and 16A depict states of formation of a source contact portion of a center portion 104 of an active region during manufacture; FIGS. 13B, 14B, 15B and 16B depict states of formation of a gate contact portion of an outer peripheral portion 114 of the active region during manufacture. Further, in FIGS. 13A to 16B, portions (front device structure, SJ structure, etc.) in a semiconductor substrate 101 are not depicted.

For example, in a SJ-MOSFET of a low breakdown voltage class such as about 600V or less, a trench contact structure is employed as a contact (electrical connection) portion between a surface electrode at a front surface of a semiconductor substrate and a predetermined portion. In manufacturing a SJ-MOSFET having such a trench contact structure, first, as depicted in FIGS. 13A and 13B, the semiconductor substrate 101 having a drift layer of a SJ structure (not depicted) is prepared and a front device structure (not depicted) is formed in the center portion 104 of the active region of the semiconductor substrate 101 (step S101).

Further, in the process at step S101, in the outer peripheral portion 114 surrounding a periphery of the center portion 104 of the active region, an insulating layer for device isolation such as a LOCOS film 111 is formed on a front surface of the semiconductor substrate 101 and a gate polysilicon wiring layer 112 is formed on the LOCOS film 111. The semiconductor substrate 101 contains single crystal silicon (Si). The front device structure includes parts (excluding p⁺⁺-type contact region 103) of a MOS gate (metal-oxide-semiconductor insulated gate) structure formed in the semiconductor substrate 101, at the front surface thereof.

Next, an interlayer insulating film 102 is formed in an entire area of the front surface of the semiconductor substrate 101 so as to cover gate electrodes and the gate polysilicon wiring layer 112 (step S102). The interlayer insulating film 102 is a silicon oxide (SiO₂) film such as borophosphosilicate glass (BPSG). Next, a resist mask 121 for etching is formed on the interlayer insulating film 102 (step S103). The resist mask 121 has openings 121a, 121b at portions respectively corresponding to formation regions of contact holes.

Next, as depicted in FIGS. 14A and 14B, the interlayer insulating film 102 is etched using the resist mask 121 (SiO₂ etching), whereby contact holes 102a, 102b that penetrate through the interlayer insulating film 102 in a depth direction are formed (step S104). In the contact hole 102a of the center portion 104 of the active region, a portion constituting the source contact portion of the semiconductor substrate 101 is exposed. In the contact hole 102b of the outer peripheral portion 114 of the active region, a portion of the gate polysilicon wiring layer 112 is exposed and constitutes a gate contact portion in contact with a gate metal wiring layer (not depicted).

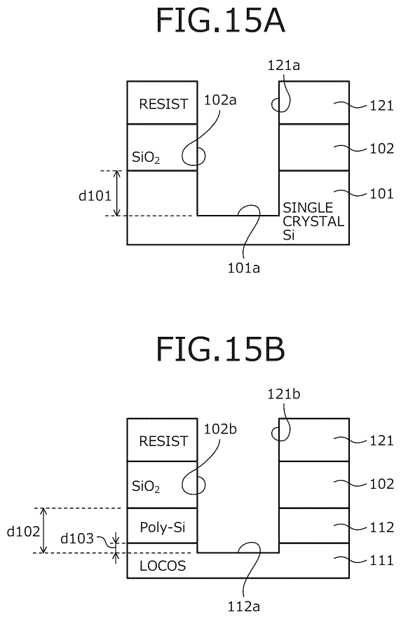

Next, as depicted in FIGS. 15A and 15B, the resist mask 121 used in the process at step S104 is used to concurrently etch (Si etching) the semiconductor substrate 101 (single crystal Si) and the gate polysilicon wiring layer 112 (polycrystalline Si (poly-Si)) thereby forming contact trenches 101a, 112a that are respectively continuous with the contact holes 102a, 102b (step S105). Here, an etching time is set so that the contact trench 101a of the center portion 104 of the active region has a predetermined depth d101.

The predetermined depth d101 of the contact trench 101a is the depth that the contact trench 101a penetrates through, in the depth direction, an n⁺-type source region (not depicted) in the semiconductor substrate 101, at the front surface thereof and is about 0.7 μm. The portion of the gate polysilicon wiring layer 112 exposed in the contact hole 102b is gradually removed in each process up to step S105, and has a thickness of about 0.5 μm at the time of step S105. Thus, the contact trench 112a penetrates though the gate polysilicon wiring layer 112 in the depth direction and terminates in the LOCOS film 111.

Thus, a thickness of the LOCOS film 111 between a bottom of the contact trench 112a and the front surface of the semiconductor substrate 101 is reduced by an etching amount (depth removed by etching) d103 of the LOCOS film 111 when the contact trench 112a is formed. The thickness of the LOCOS film 111 between the bottom of the contact trench 112a and the front surface of the semiconductor substrate 101 has to be left at a predetermined thickness that ensures insulation that may withstand a power supply voltage used in a circuit in which the semiconductor device of the reference example is mounted. When the thickness of the LOCOS film 111 is about 0.5 μm, an allowable upper limit of the etching amount d103 of the LOCOS film 111 is about 0.30 μm.

However, due to differences in the crystal arrangements of single crystal Si and poly-silicon, etching rates (=the etching amount/the etching time) thereof differ. In general, poly-silicon has an etching rate that is at least about 20% higher than that of single crystal Si and thus, is easier to etch than is the single crystal Si. For example, by an estimation based on experimental results, the inventors confirmed that the etching rate of poly-silicon is about 26% to 27% higher than the etching rate of single crystal silicon (refer to later-described FIG. 11). Thus, when a depth d102 of the contact trench 112a becomes significantly deeper as compared to the depth d101 of the contact trench 101a and the etching of the LOCOS film 111 progresses too far, the LOCOS film 111 may not be left having the predetermined thickness.

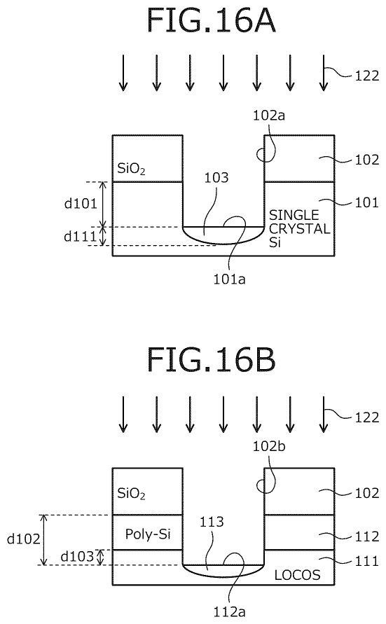

Next, as depicted in FIGS. 16A and 16B, the resist mask 121 is removed (step S106) and thereafter, the interlayer insulating film 102 is used as an ion implantation mask and a p-type dopant is implanted by an ion implantation 122 thereby forming the p⁺⁺-type contact region 103 in the semiconductor substrate 101, at a portion thereof exposed at the bottom of the contact trench 101a (step S107). Here, the p-type dopant is further ion-implanted in the LOCOS film 111, at a portion thereof exposed at the bottom of the contact trench 112a thereby forming a p⁺⁺-type dopant region 113 in the LOCOS film 111, at the surface thereof.

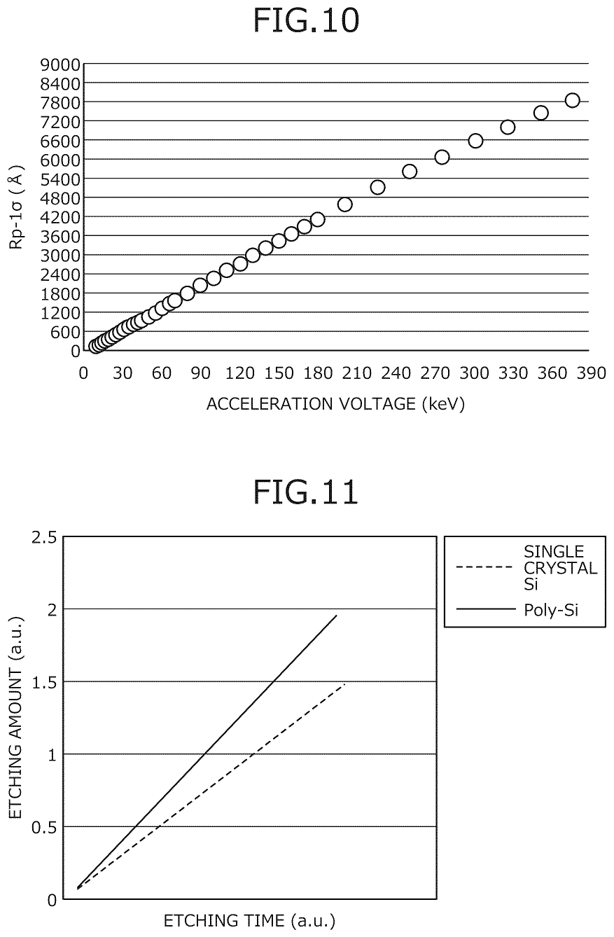

An acceleration voltage of the ion implantation 122 is set so that a range (implantation depth d111) of the ion implantation 122 is a sum of a thickness of a silicide layer (not depicted, for example, about 0.06 μm) occurring at the bottom of the contact trench 101a due to a subsequent contact annealing and a design thickness of the p⁺⁺-type contact region 103 (more than 0.06 μm) (refer to later-described FIG. 10). In an instance in which an ion species of the ion implantation 122 is boron ions (B⁺), the acceleration voltage of the ion implantation 122 is within a range of about 10 keV to 60 keV.

Thereafter, surface electrodes (not depicted) constituting a source electrode and the gate metal wiring layer are formed at the front surface of the semiconductor substrate 101 and a surface electrode (not depicted) constituting a drain electrode is formed at a back surface of the semiconductor substrate 101 (step S108), thereby completing the semiconductor device of the reference example (SJ-MOSFET). The source electrode is embedded in the contact hole 102a and the contact trench 101a and at an inner wall of the contact trench 101a, forms the source contact portion with the semiconductor substrate 101 (n⁺-type source regions and the p⁺⁺-type contact region 103).

The gate metal wiring layer is embedded in the contact hole 102b and the contact trench 112a, and at the contact trench 112a, forms the gate contact portion with the gate polysilicon wiring layer 112. As described above, during the process at step S105, when the etching of the LOCOS film 111 progresses too far and the allowable upper limit of the etching amount d103 of the LOCOS film 111 is exceeded, between the bottom of the contact trench 112a and the front surface of the semiconductor substrate 101, the LOCOS film 111 becomes thin or the LOCOS film 111 disappears and the necessary predetermined thickness thereof cannot be ensured for a portion of the LOCOS film 111.

As a result, Time Zero Dielectric Breakdown (TZDB) breakdown voltage strength at the LOCOS film 111 decreases. Further, at the bottom of the contact trench 112a, the p⁺⁺-type dopant region 113 penetrates through the LOCOS film 111 in the depth direction and reaches the semiconductor substrate 101 or may be directly formed in the semiconductor substrate 101. Further, at the bottom of the contact trench 112a, the gate metal wiring layer may be in contact with the semiconductor substrate 101.

In the present embodiment, when parts containing differing materials (the semiconductor substrate 101 and the gate polysilicon wiring layer 112) are concurrently processed by etching, the difference of the etching amounts of the parts is reduced, thereby improving the reliability of the semiconductor device.

Embodiments of a method of manufacturing a semiconductor device according to the present disclosure will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Depending on the structure that is optimal, the concentrations may be reversed. In the description of the embodiments below and the accompanying drawings, main portions that are identical will be given the same reference numerals and will not be repeatedly described.

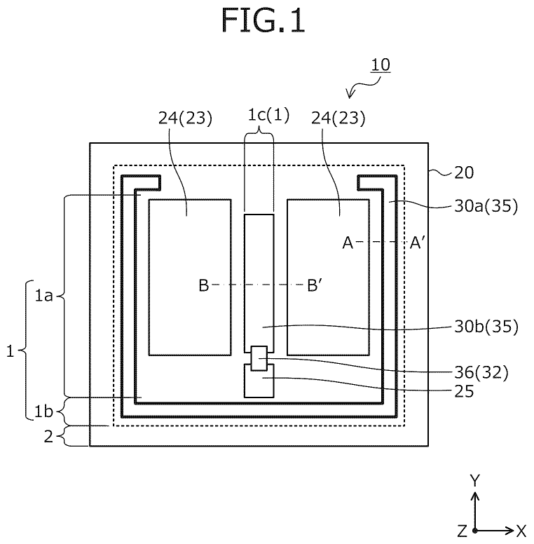

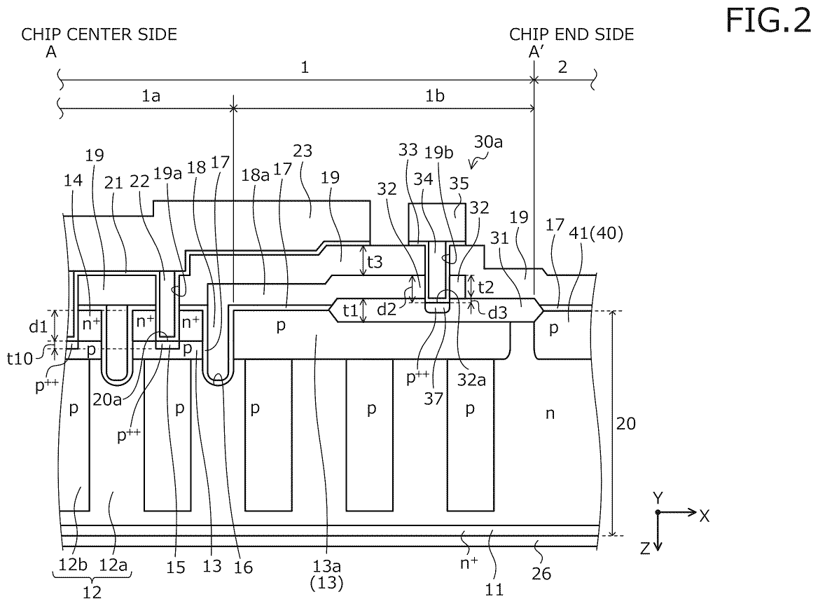

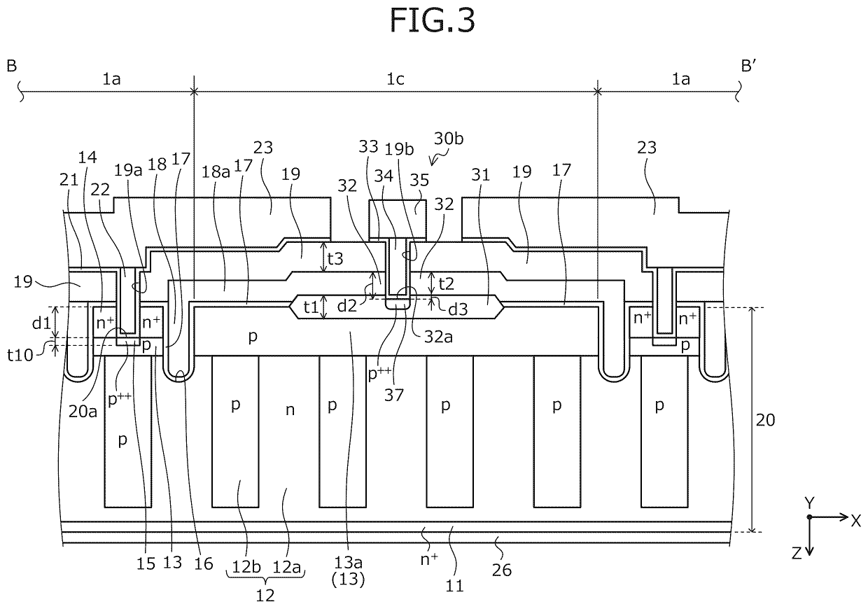

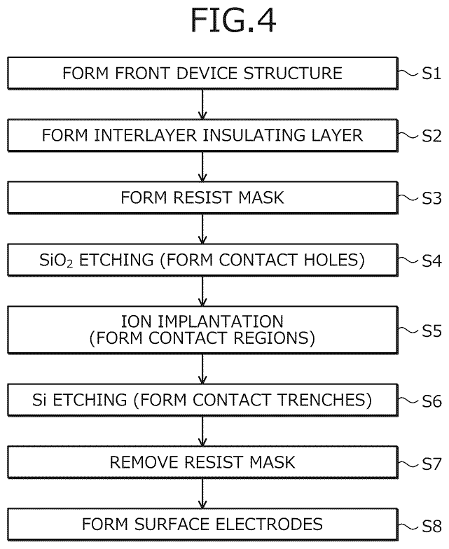

Herein, a method of manufacturing a semiconductor device according to an embodiment is described. FIG. 1 is a plan view depicting an example of a layout when a semiconductor device manufactured according to the method of manufacturing a semiconductor device according to the embodiment is viewed from a front side of a semiconductor substrate thereof. FIGS. 2 and 3 are, respectively, a cross-sectional view depicting an example of a structure along cutting line A-A′ and cutting line B-B′ in FIG. 1. A semiconductor device 10 (hereinafter, the semiconductor device 10 according to the embodiment: FIGS. 1 to 3) fabricated (manufactured) by the method of manufacturing the semiconductor device according to the embodiment has a trench contact structure in portions formed of differing materials in a semiconductor substrate (semiconductor chip) 20, at a front surface thereof and is fabricated by the later-described method of manufacturing a semiconductor device according to the embodiment (refer to FIG. 4).

The semiconductor device 10 according to the embodiment may be, for example, a super-junction metal oxide semiconductor field effect transistor (SJ-MOSFET), the SJ having a parallel pn layer 12 in which n-type column regions 12a and p-type column regions 12b are disposed repeatedly alternating with each other in a direction parallel to main surfaces (front surface and back surface) of a semiconductor substrate 20 being provided as drift layer, and the MOSFET having insulated gates with a metal-oxide-semiconductor three-layer structure. The semiconductor device 10 according to the embodiment has, for example, trench contact structures, respectively, in a single crystal silicon (Si) portion and a poly-silicon (polycrystalline Si (poly-Si)) portion.

The trench contact structures are structures in which contact trenches that are continuous with contact holes penetrating through an interlayer insulating film 19 in a depth direction Z are formed below the interlayer insulating film 19, and a contact (electrical connection) portion between a surface electrode and a predetermined portion is formed at an inner wall of each of the contact trenches. For example, a source contact portion between the source electrode (surface electrode, first electrode) 23 and the semiconductor substrate (single crystal silicon region) 20, and a gate contact portion between a gate metal wiring layer (surface electrode, second electrode) 35 and gate polysilicon wiring layer (polycrystalline silicon region) 32 are each a trench contact structure. Contact trenches 20a, 32a configuring the respective trench contact structures are formed concurrently by etching.

As depicted in FIG. 1, at the front surface of the semiconductor substrate 20, multiple surface electrodes such as the source electrode 23 (source pad 24), a gate pad 25, and the gate metal wiring layer 35 are provided. The source electrode 23 and the gate pad 25 are provided in a center portion (first device region) 1a of an active region 1. A portion of the source electrode 23 is exposed in an opening of a passivation film and constitutes the source pad 24. The source electrode 23 may be provided in plural apart from each other. The gate metal wiring layer 35 configures a gate ring 30a and is provided in an outer peripheral portion (second device region) 1b of the active region 1. The gate metal wiring layer 35 configures a gate finger 30b and, for example, may be provided in a portion (hereinafter, non-operating region) 1c that is free of cells between adjacent source electrodes 23.

The gate ring 30a surrounds a periphery of the center portion 1a of the active region 1 in a substantially rectangular shape (or partially open rectangular shape) in a plan view. The gate ring 30a is electrically connected to a gate resistor 36 in a non-depicted portion. Gate electrodes 18 of all cells of the MOSFET are continuous with the gate ring 30a and the gate finger 30b (FIGS. 2 and 3). The gate ring 30a and the gate finger 30b are electrically connected to the gate pad 25 via the gate resistor 36. In an edge termination region 2, a source ring (not depicted) fixed to a potential of the source electrode 23 may be provided. The source ring surrounds a periphery of the active region 1 in substantially a rectangular shape in a plan view and, for example, is continuous with the source electrode 23 in an open portion of the gate ring 30a.

In the semiconductor substrate 20, multiple MOSFET cells of a same structure (functional unit of a device) are disposed adjacent to each other in the center portion 1a of the active region 1. The active region 1 is a region through which a main current flows when the MOSFET is on. The active region 1 has a substantially rectangular shape in a plan view and is disposed in substantially a center (chip center) of the semiconductor substrate 20. The edge termination region 2 is a region between the active region 1 and a chip end (end of the semiconductor substrate 20) and surrounds the periphery of the active region 1 in substantially a rectangular shape in a plan view. In the edge termination region 2, a predetermined voltage withstanding structure 40 formed by a p-type region 41 is provided. The voltage withstanding structure 40 has a function of relaxing electric field near a border between the active region 1 and the edge termination region 2 and sustaining a breakdown voltage. The breakdown voltage is a maximum voltage at which no malfunction or destruction of the semiconductor device 10 occurs.

As depicted in FIGS. 2 and 3, in the active region 1, the parallel pn layer 12 constituting a drift layer is provided in the semiconductor substrate 20. The n-type column regions 12a and the p-type column regions 12b configuring the parallel pn layer 12 are disposed repeatedly alternating with each other in a first direction X parallel to the main surfaces of the semiconductor substrate 20. The n-type column regions 12a and the p-type column regions 12b, for example, extend in a second direction Y that is parallel to the main surfaces of the semiconductor substrate 20 and orthogonal to the first direction X. The n-type column regions 12a and the p-type column regions 12b may be provided spanning the active region 1 and the edge termination region 2. Alternatively, the drift layer may be formed by the parallel pn layer 12 only in a portion closer to the chip center than is a local oxidation of silicon (LOCOS) film 31 while directly below the LOCOS film 31 and in the edge termination region 2, the drift layer may be configured by an n-type region having a dopant concentration that is a same at that of the n-type column regions 12a or an n⁻-type region having a dopant concentration that is lower than that of the n-type column regions 12a without the drift layer being formed by the parallel pn layer.

The semiconductor substrate 20 contains single crystal Si. An n⁺-type drain region 11 is provided between the back surface of the semiconductor substrate 20 and the drift layer. A p-type base region 13 is provided in the active region 1, in an entire area between the front surface of the semiconductor substrate 20 and the parallel pn layer 12, the p-type base region 13 terminating in the outer peripheral portion 1b of the active region 1. Between the front surface of the semiconductor substrate 20 and the p-type base region 13, n+-type source regions 14 are provided. The n⁺-type source regions 14 reach sidewalls of the later-described contact trenches 20a in a direction (the first direction X) parallel to the front surface of the semiconductor substrate 20. The n⁺-type source regions 14 each has a bottom (lower surface: end facing the back surface of the semiconductor substrate 20) in contact with the p-type base region 13. The n⁺-type source regions 14 are provided only in the center portion 1a of the active region 1.

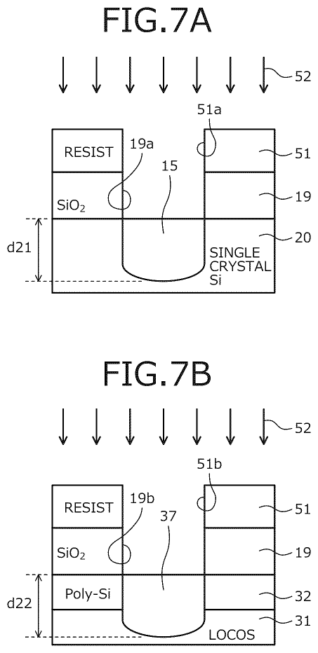

In an entire area between the p-type base region 13 and bottom surfaces of the contact trenches 20a, p⁺⁺-type contact regions (first regions) 15 are provided in contact with the p-type base region 13. The p⁺⁺-type contact regions 15 reach the bottom surfaces of the contact trenches 20a. The p⁺⁺-type contact regions 15 may reach the sidewalls from the bottom surfaces of the contact trenches 20a. The p⁺⁺-type contact regions 15 are amorphous because covalent bonds (Si—Si bonds) of the single crystal Si are broken by an ion implantation 52 (refer to later-described FIG. 7A) for forming the p⁺⁺-type contact regions 15. The p⁺⁺-type contact regions 15, despite being amorphous have a function of reducing contact resistance of the source contact portion, similar the p⁺⁺-type contact region 103 (refer to FIG. 16A) of the reference structure.

The p⁺⁺-type contact regions 15 may contain a dopant other than an accepter dopant implanted by the ion implantation 52 for forming the p⁺⁺-type contact regions 15. The dopant other than the accepter dopant implanted by the ion implantation 52 for forming the p⁺⁺-type contact regions 15 is, for example, fluorine (F) and in this instance, the p⁺⁺-type contact regions 15 contain Si—F bonds. The n⁺-type drain region 11, the p-type column regions 12b, the p-type base region 13, the n⁺-type source regions 14, and the p⁺⁺-type contact regions 15 are dopant diffused regions formed in the semiconductor substrate 20 by ion implantation. The n-type column regions 12a are portions of the n-type semiconductor substrate 20 free of ion implantation.

Gate trenches 16 penetrate through the n⁺-type source regions 14 and the p-type base region 13 in the depth direction Z and terminate in the n-type column regions 12a. Between the p-type column regions 12b adjacent to each other in the first direction X, the gate trenches 16 are provided apart from the p-type column regions 12b and extend linearly in the second direction Y. Each of the n-type column regions 12a is interposed between one of the gate trenches 16 and one of the p-type column regions 12b. In the gate trenches 16, the gate electrodes 18 are provided via gate insulating films 17. A trench gate structure is configured by the p-type base region 13, the n⁺-type source regions 14, the p⁺⁺-type contact regions 15, the gate trenches 16, the gate insulating films 17, and the gate electrodes 18.

Between the gate trenches 16 that are adjacent to each other, for example, in substantially a center therebetween, each of the contact trenches (first contact trenches) 20a is provided apart from the gate trenches 16. The contact trenches 20a reach a predetermined depth d1 from the front surface of the semiconductor substrate 20 in the depth direction Z and terminate at upper surfaces (ends facing the front surface of the semiconductor substrate 20) of the p⁺⁺-type contact regions 15 or in the p⁺⁺-type contact regions 15. At inner walls of the contact trenches 20a, the n⁺-type source regions 14 and the p++-type contact regions 15 are exposed. Each of the n⁺-type source regions 14 is provided between a corresponding one of the gate trenches 16 and one of the contact trenches 20a adjacent thereto, spanning between a sidewall of said gate trench 16 and a sidewall of said contact trench 20a facing each other.

The outer peripheral portion 1b of the active region 1 surrounds the periphery of the center portion 1a of the active region 1 in a substantially rectangular shape in a plan view. The outer peripheral portion 1b of the active region 1 is free of MOSFET cells. In the outer peripheral portion 1b of the active region 1, the p-type base region 13 (hereinafter, a p-type outer peripheral region 13a), the gate insulating films 17, and the gate electrodes 18 extend from the center portion 1a of the active region 1. The p-type outer peripheral region 13a is exposed at the front surface of the semiconductor substrate 20 and is in contact with an insulating layer (insulating layer formed by the gate insulating films 17, the LOCOS film 31, and the interlayer insulating film 19) on the front surface of the semiconductor substrate 20. The p-type outer peripheral region 13a surrounds the periphery of the center portion 1a of the active region 1 in a plan view. The p-type outer peripheral region 13a is electrically connected to the source electrode 23 in a non-depicted region.

In the outer peripheral portion 1b of the active region 1, in the semiconductor substrate 20, at the front surface thereof, the LOCOS film 31 formed by thermal oxidation of the front surface of the semiconductor substrate 20. The LOCOS film 31 is an insulating layer for device isolation (field oxide film) and has a relatively thick thickness for electrically isolating the front device structure of the center portion 1a of the active region 1 from the periphery. The LOCOS film 31 surrounds the periphery of the center portion 1a of the active region 1 in a substantially rectangular shape in a plan view. The LOCOS film 31 extends in the edge termination region 2 and is in contact with the voltage withstanding structure 40. The p-type outer peripheral region 13a intervenes between the LOCOS film 31 and the drift layer. The LOCOS film 31 and the p-type outer peripheral region 13a extend in the non-operating region 1c.

The interlayer insulating film 19 is provided in an entire area of the front surface of the semiconductor substrate 20 and covers the gate electrodes 18 and the LOCOS film 31. The interlayer insulating film 19, for example, is a stacked film including a high temperature oxide (HTO) film and a silicon oxide (SiO₂) film such as a borophosphosilicate glass (BPSG) film or the like. The gate insulating films 17 may extend between the interlayer insulating film 19 and the front surface of the semiconductor substrate 20 in the outer peripheral portion 1b of the active region 1 and the non-operating region 1c, and in the edge termination region 2. In the outer peripheral portion 1b of the active region 1 and the non-operating region 1c, a gate polysilicon wiring layer 32 is provided between the LOCOS film 31 and the interlayer insulating film 19.

The gate polysilicon wiring layer 32 surrounds the periphery of the center portion 1a of the active region 1 in a plan view. The gate polysilicon wiring layer 32, for example, is configured by portions of the gate electrodes 18 extended on the front surface of the semiconductor substrate 20. The gate polysilicon wiring layer 32 surrounds the periphery of the center portion 1a of the active region 1 in a plan view, configures the gate ring 30a, extends linearly in the non-operating region 1c, and configures the gate finger 30b. A portion of the gate polysilicon wiring layer 32 configures the gate resistor 36 (refer to FIG. 1). The contact trench (second contact trench) 32a is provided penetrating through the gate polysilicon wiring layer 32 in the depth direction Z and terminating in the LOCOS film 31. The contact trench 32a surrounds the periphery of the center portion 1a of the active region 1 and extends linearly in the non-operating region 1c.

At sidewalls of the contact trench 32a, the gate polysilicon wiring layer 32 is exposed. In the LOCOS film 31, a p⁺⁺-type dopant region (second region) 37 is provided facing a bottom of the contact trench 32a. The p⁺⁺-type dopant region 37 is in contact with the bottom of the contact trench 32a and underlies an entire surface of the bottom of the contact trench 32a. The p⁺⁺-type dopant region 37 may reach the sidewalls of the contact trench 32a from the bottom of the contact trench 32a. The p⁺⁺-type dopant region 37 may not reach the semiconductor substrate 20 with a portion of the LOCOS film 31 excluding the p⁺⁺-type dopant region 37 (portion free of ion implantation) intervening between the p⁺⁺-type dopant region 37 and the semiconductor substrate 20. The p⁺⁺-type dopant region 37 may be omitted.

In the interlayer insulating film 19, contact holes 19a, 19b that penetrate through the interlayer insulating film 19 in the depth direction Z are provided. Each of the contact holes (first contact holes) 19a has a width that is substantially a same as that of each of the contact trenches 20a, the contact holes (first contact holes) 19a being continuous with the contact trenches 20a in the depth direction Z, respectively. In the contact holes 19a, the n⁺-type source regions 14 and the p⁺⁺-type contact regions 15 of the inner walls of the contact trenches 20a are exposed. The contact hole (second contact hole) 19b has a width that is substantially a same as that of the contact trench 32a and is continuous with the contact trench 32a in the depth direction Z. In the contact hole 19b, the gate polysilicon wiring layer 32 of an inner wall of the contact trench 32a is exposed.

Along the sidewalls (sidewalls of the interlayer insulating film 19) of the contact holes 19a and the inner walls of the contact trenches 20a, a barrier metal 21 is provided; and in the contact holes 19a and the contact trenches 20a, plugs 22 are embedded on the barrier metal 21. Along the sidewalls of the contact hole 19b and the inner wall of the contact trench 32a, a barrier metal 33 is provided; and in the contact hole 19b and the contact trench 32a, a plug 34 is embedded on the barrier metal 33.

The barrier metals 21, 33, for example, is a single layer of a titanium (Ti) film or a titanium nitride (TiN) film or a stacked film thereof. The barrier metals 21, 33 have a function of improving adhesion of the plugs 22,34 and preventing interaction between parts facing each other across the barrier metals 21, 33. A silicide (TixSiy, where, x, y are integers) layer is formed at the inner walls of the contact trenches 20a by a silicide reaction between the barrier metal 21 and the semiconductor substrate 20. The plugs 22, 34, for example, are tungsten (W) films having high embeddability in the contact trenches 20a, 32a.

The source electrode 23 is provided on the interlayer insulating film 19 and the contact holes 19a in substantially an entire area of the center portion 1a of the active region 1 and is connected to the barrier metal 21 and the plugs 22 in the contact holes 19a. The source electrode 23 forms a source contact portion with the semiconductor substrate 20 at the inner walls of the contact trenches 20a via the barrier metal 21 and the plugs 22, and is electrically connected to the n⁺-type source regions 14 and the p⁺⁺-type contact regions 15. The barrier metal 21 may extend between the source electrode 23 and the interlayer insulating film 19, from the sidewalls of the contact holes 19a.

The gate metal wiring layer 35 is provided on the interlayer insulating film 19 and the contact hole 19b, at a position facing the gate polysilicon wiring layer 32 in the depth direction Z, and is connected to the barrier metal 33 and the plug 34 in the contact hole 19b. The gate metal wiring layer 35 forms a gate contact portion with the gate polysilicon wiring layer 32 at the contact trench 32a, via the barrier metal 33 and the plug 34. The barrier metal 33 may extend between the gate metal wiring layer 35 and the interlayer insulating film 19, from the sidewalls of the contact hole 19b.

The gate metal wiring layer 35 and the gate polysilicon wiring layer 32 configure the gate ring 30a and the gate finger 30b. The source electrode 23, the gate pad 25, and the gate metal wiring layer 35, for example, may be an aluminum (Al) film or an aluminum-silicon (Al—Si) film. In an entire area of the back surface of the semiconductor substrate 20, a surface electrode constituting a drain electrode 26 is provided. The drain electrode 26 is electrically connected to an n⁺-type drain region 11 at the back surface of the semiconductor substrate 20.

While not particularly limited hereto, for example, dimensions of regions are as follows. A thickness t1 of the LOCOS film 31 is 0.5 μm. A thickness t2 of the gate polysilicon wiring layer 32 is 0.5 μm. A total thickness t3 of the interlayer insulating film 19 is 0.8 μm (BPSG: 0.6 μm, HTO: 0.2 μm). The depth d1 of the contact trenches 20a is 0.70 μm. A depth d2 of the contact trench 32a is not more than 0.80 μm and preferably, may be 0.70 μm or less. A depth (the etching amount d3 of the LOCOS film 31) from an interface between the gate polysilicon wiring layer 32 and the LOCOS film 31 to the bottom of the contact trench 32a is not more than an allowable upper limit 0.30 μm of the etching amount d3 of the LOCOS film 31 and preferably, may be 0.20 μm or less.

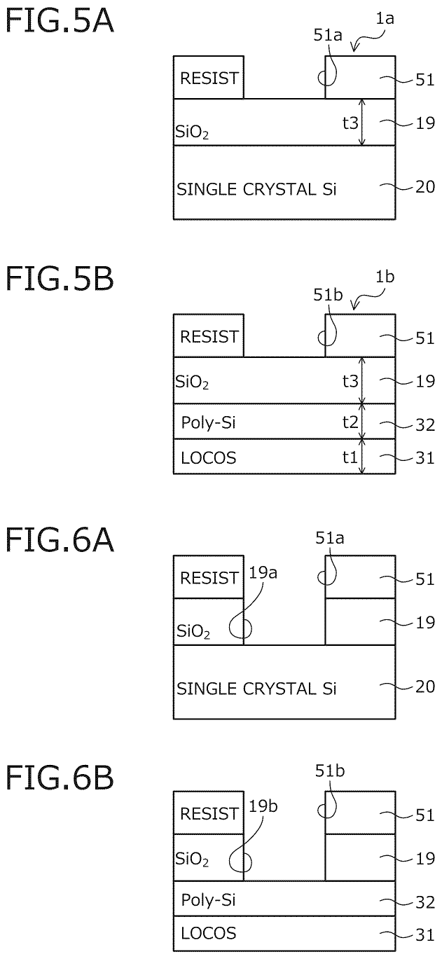

FIG. 4 is a flowchart depicting an outline of the method of manufacturing the semiconductor device according to the embodiment. FIGS. 5A, 5B, 6A, 6B, 7A, 7B, 8A, 8B, 9A, and 9B are cross-sectional views schematically depicting states of the semiconductor device according to the embodiment during manufacture. FIGS. 5A, 6A, 7A, 8A, and 9A depict states of the formation of the source contact portion during manufacture; FIGS. 5B, 6B, 7B, 8B, and 9B depict states of the formation of the gate contact portion during manufacture. Further, in FIGS. 5A to 9B, parts (the front device structure and the SJ structure) in the semiconductor substrate 20 are not depicted.

In manufacturing the semiconductor device 10 according to the embodiment (SJ-MOSFET) depicted in FIGS. 1 to 3 described above, first, as depicted in FIG. 5, the semiconductor substrate 20 having the drift layer with the SJ structure (not depicted) formed by the n-type column regions 12a and the p-type column regions 12b is prepared or fabricated, and in the center portion 1a of the active region 1 of the semiconductor substrate 20, the front device structure is formed in the semiconductor substrate 20, at the front surface thereof (step S1).

Further, in the process at step S1, in the outer peripheral portion 1b and the non-operating region 1c of the active region, the LOCOS film 31 is formed at the front surface of the semiconductor substrate 20 by thermal oxidation, and the gate polysilicon wiring layer 32 is deposited on the LOCOS film 31 by a chemical vapor deposition (CVD) method. The front device structure is the trench gate structure (excluding the p⁺⁺-type contact regions 15). The gate polysilicon wiring layer 32, for example, may be formed concurrently with the gate electrodes 18 configuring the trench gate structure.

Next, by a CVD method or the like, the interlayer insulating film 19 is deposited (formed) in an entire area of the front surface of the semiconductor substrate 20, so as to cover the gate electrodes 18 and the gate polysilicon wiring layer 32 (step S2: first process). Next, on the interlayer insulating film 19, a resist mask 51 for etching is formed (step S3: second process). In the resist mask 51, openings 51a, 51b are formed at portions corresponding to formation regions of the contact holes 19a, 19b of the interlayer insulating film 19, the openings 51a, 51b being formed by etching using, for example, an oxide film mask (not depicted) as a mask.

Next, as depicted in FIGS. 6A and 6B, the interlayer insulating film 19 is etched (SiO₂ etching) using the resist mask 51 as an etching mask, whereby the contact holes 19a, 19b that penetrate through the interlayer insulating film 19 in the depth direction Z are formed (step S4). In the contact holes 19a, the semiconductor substrate 20 (the n⁺-type source regions 14) are exposed. In the contact hole 19b, the gate polysilicon wiring layer 32 is exposed. At etching process at step S4 is anisotropic etching by dry etching.

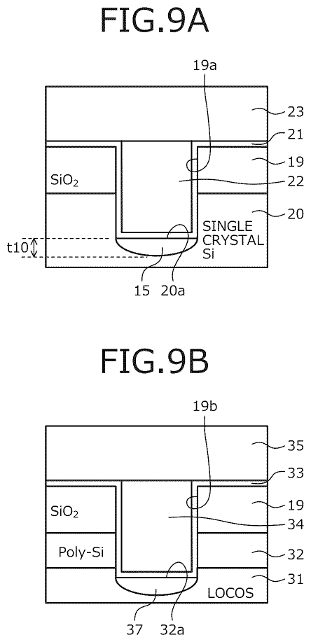

Next, as depicted in FIG. 7A, similarly as during the process at step S4, the resist mask 51 and the interlayer insulating film 19 are used as an ion implantation mask and a p-type dopant is implanted by the ion implantation 52, thereby forming the p⁺⁺-type contact regions 15 in portions of the semiconductor substrate 20 exposed in the contact holes 19a (step S5: third process). An implantation depth (depth of the p⁺⁺-type contact regions 15) d21 of the ion implantation 52 is set so that when the semiconductor device 10 is completed, the p⁺⁺-type contact regions 15 are left at the bottom surfaces of the contact trenches 20a, having a design thickness t10 (refer to FIG. 9A).

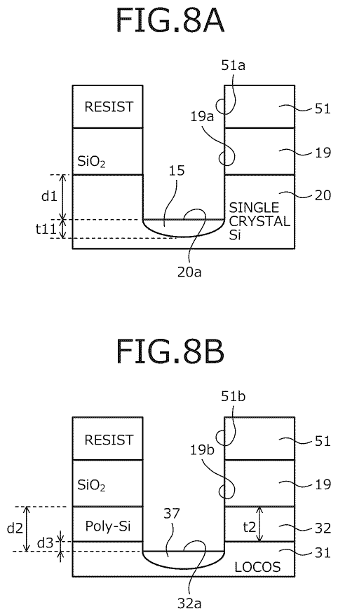

For example, the acceleration voltage of the ion implantation 52 is set so that the range of the ion implantation 52 (Rp-standard deviation (1σ)=the implantation depth d21) at step S5 is a sum (more than 0.76 μm) of the depth d1 of the contact trenches 20a (refer to FIG. 8A, for example, about 0.7 μm) formed by a subsequent process, a thickness (not depicted, for example, about 0.06 μm) of a silicide (TixSiy) layer formed at the bottom surfaces of the contact trenches 20a by a subsequent contact annealing treatment, and the design thickness t10 of the p⁺⁺-type contact regions 15.

For example, the acceleration voltage for the ion implantation 52 may be easily obtained by calculating, in advance, the range of ion implantation into single crystal Si as a function of the acceleration voltage for the ion implantation for the ion species used in the ion implantation 52 (refer to later-described FIG. 10). For the ion implantation 52, boron (B) or boron fluoride (BF₂) is often used (i.e., monovalent boron ion (B⁺) or divalent boron ion (B⁺⁺) is used), which easily breaks the covalent bond of the single crystal Si and preferably, BF₂⁺ (an ion species containing an F atom that easily reacts with Si atoms), which more easily breaks the covalent bond of the single crystal Si may be used.

B⁺ or BF₂⁺, which are p-type dopants, is used as the ion species of the ion implantation 52 and thus, formation of the p⁺⁺-type contact regions 15 and the breaking of covalent bonds of the single crystal Si of the semiconductor substrate 20 may be performed concurrently. Further, it has been demonstrated that an ion species such as B⁺ and BF₂⁺ may form the p⁺⁺-type contact regions 15, which realize low resistance source contact portions. Thus, design of the semiconductor device 10 may be simplified. The ion species used in the ion implantation 52 may be suitably set and conditions of the ion implantation 52 suffice to be suitably set according to the ion species.

For example, when the ion species of the ion implantation 52 is B⁺, the acceleration voltage of the ion implantation 52 is in a range of about 300 keV to 450 keV, and is about 375 keV. When the ion species of the ion implantation 52 is BF₂⁺, the acceleration voltage of the ion implantation 52 is in a range of about 2500 keV to 3750 keV, and is about 3250 keV. A dose amount of the ion implantation 52 is in a range of about 1.00×10¹⁴ ions/cm² to 1.00×10¹⁶ ions/cm², regardless of whether the ion species is B⁺ or BF₂⁺. The acceleration voltage of the ion implantation 52 may be set so that a peak (maximum concentration) of implanted ion concentration is at a depth position about 0.40 μm to 0.90 μm from the ion-implanted surface of the ion implantation.

The formation of the p⁺⁺-type contact regions 15 and the breaking of the covalent bonds of the single crystal Si of the semiconductor substrate 20 may be performed as separate processes. In this instance, for example, an ion implantation of a p-type dopant for forming the p⁺⁺-type contact regions 15, and for example, an ion implantation of an inert species such as argon ions (Ar⁺) for breaking the covalent bonds of the single crystal Si of the semiconductor substrate 20 are performed. In an instance in which the ion species of the ion implantation 52 is a dopant such as Ar⁺, which is not usually used in the formation of parts of the semiconductor device 10, preferably, consideration may be given to whether the ion implantation 52 would adversely affect the device structure.

In portions (the p⁺⁺-type contact regions 15) subjected to the ion implantation 52, the covalent bonds of the single crystal Si of the semiconductor substrate 20 are broken and the portions become amorphous (Si—Si bonds are weakened), whereby the etching rate of the p⁺⁺-type contact regions 15 (=the etching amount/the etching time) increases. As a result, throughput of the etching process at step S6 is improved. Further, as described above, in general, while the etching rate of poly-silicon is higher than the etching rate of single crystal Si, the covalent bonds of the single crystal Si of the semiconductor substrate 20 are broken by the ion implantation 52 whereby the etching rate of the p⁺⁺-type contact regions 15 is increased, thereby bringing the etching rate of the p⁺⁺-type contact regions 15 closer to the etching rate of poly-silicon.

Further, the p⁺⁺-type dopant region 37 is formed by the ion implantation 52 at step S5, at the portion of the gate polysilicon wiring layer 32 exposed in the contact hole 19b. In the portion (the p⁺⁺-type dopant region 37) subjected to the ion implantation 52, bonds of the poly-silicon (set of the single crystal Si of differing crystal orientation) of the gate polysilicon wiring layer 32 are broken. The covalent bonds of the single crystal Si are stronger than the bonds of the poly-silicon and thus, an increase of the etching rate of the p⁺⁺-type contact regions 15 by breaking the covalent bonds of the single crystal Si is sufficiently large as compared to the increase of the etching rate of the p⁺⁺-type dopant region 37 by breaking the bonds of the poly-silicon, and the etching rate of the p⁺⁺-type contact regions 15 is brought closer to the etching rate of the p⁺⁺-type dopant region 37.

The portion of the gate polysilicon wiring layer 32 exposed in the contact hole 19b is gradually removed at each process up to that at step S5 and during the process at step S5, the thickness t2 is, for example, about 0.5 μm. An implantation depth d 22 of the ion implantation 52 at the p⁺⁺-type dopant region 37 reaches at least the implantation depth d21 (more than 0.76 μm) of the ion implantation 52 of the p⁺⁺-type contact regions 15. Thus, the p⁺⁺-type dopant region 37 penetrates through the gate polysilicon wiring layer 32 in the depth direction Z and terminates in the LOCOS film 31. The covalent bonds of the single crystal Si of the p⁺⁺-type contact regions 15 may be broken by the ion implantation 52 and application of the ion implantation 52 to the gate polysilicon wiring layer 32 may be omitted.

Next, as depicted in FIG. 8A, the resist mask 51 and the interlayer insulating film 19 used in the process at step S5 are used as etching masks, and the p⁺⁺-type contact regions 15 (portions where the covalent bonds of the single crystal Si of the semiconductor substrate 20 are broken) and the p⁺⁺-type dopant region 37 (portion where the bonds of the poly-silicon of the gate polysilicon wiring layer 32 are broken) are etched concurrently (Si etching), whereby the contact trenches 20a, 32a are formed continuous with the contact holes 19a, 19b, respectively (step S6: fourth process).

For the etching process at step S6, etching conditions (for example, the etching time) are set so that the contact trenches 20a have the predetermined depth d1. Further, the etching process at step S6 is anisotropic etching by dry etching. As described above, during the process at step S5, the implantation depth d21 (refer to FIG. 7A) of the p⁺⁺-type contact regions 15 is set taking into account the depth d1 of the contact trenches 20a, so that the p++-type contact regions 15 may be left with a predetermined remaining thickness t11 at the bottom surfaces of the contact trenches 20a.

Further, as described above, the etching rate of the p⁺⁺-type contact regions 15 approaches the etching rate of the p⁺⁺-type dopant region 37 and thus, the depth d2 of the contact trench 32a shallow as compared to the depth d102 of the contact trench 112a (refer to FIG. 16B) of the reference example. Even when the semiconductor substrate 20 and the gate polysilicon wiring layer 32 are etched concurrently, the depth d2 of the contact trench 32a is shallow, whereby the etching amount (depth removed by etching) d3 of the LOCOS film 31 is reduced.

The etching rate of the LOCOS film is at least about 20% smaller than the etching rate of the single crystal Si. When the contact trenches 20a, 32a are formed, during the period while the LOCOS film 31 is etched, the etching amount (the etching amount of the LOCOS film 31) of the p⁺⁺-type dopant region 37 is smaller than the etching amount of the p⁺⁺-type contact regions 15. Thus, the depth d2 of the contact trench 32a may be equal to or less than the depth d1 of the contact trenches 20a. At the bottom of the contact trench 32a, the p⁺⁺-type dopant region 37 may be left.

For example, in the method of manufacturing the semiconductor device of the reference example, at step S105, when the contact trench 112a is formed, the etching amount d103 of the LOCOS film 111 is about 0.30 μm whereas in the method of manufacturing the semiconductor device according to the embodiment, it has been confirmed by estimation based on experimental results by the present disclosure that at step S6, when the contact trench 32a is formed, the etching amount d3 of the LOCOS film 31 is reduced to be not more than about 0.20 μm.

The LOCOS film 31 may be slightly etched when the contact trench 32a is formed, provided the thickness of the LOCOS film 31 between the bottom of the contact trench 32a and the front surface of the semiconductor substrate 20 is left at a predetermined thickness that ensures insulation that may withstand the power supply voltage used in a circuit incorporating the semiconductor device 10. In the process at step S6, for example, a fluorine (F) based etching gas is used, and the semiconductor substrate 20 and the gate polysilicon wiring layer 32 are etched by a reaction of Si atoms and F atoms.

Next, as depicted in FIGS. 9A and 9B, the resist mask 51 is removed by ashing (step S7) and thereafter, the plugs 22 are embedded in the contact holes 19a and the contact trenches 20a via the barrier metal 21; and the plug 34 is embedded in the contact hole 19b and the contact trench 32a via the barrier metal 33. Next, the surface electrodes constituting the source electrode 23, the gate pad 25, and the gate metal wiring layer 35 are formed at the front surface of the semiconductor substrate 20, and a surface electrode constituting the drain electrode 26 is formed at the back surface of the semiconductor substrate 20 (step S8: fifth process, sixth process).

Next, the barrier metal 21 and the semiconductor substrate 20 are caused to react with each other (contact annealing) by a rapid thermal annealing (RTA) treatment, thereby forming a silicide layer at the inner walls of the contact trenches 20a. As described above, during the process at step S5, the implantation depth d21 of the p⁺⁺-type contact regions 15 is set taking into account the thickness of the silicide layer (refer to FIG. 7A) and thus, the p++-type contact regions 15 are left having the design thickness t10 at the bottom surfaces of the contact trenches 20a. Thus, the semiconductor device 10 depicted in FIGS. 1 to 3 is completed.

As described above, according to the embodiment, poly-silicon and ion implanted regions of the single crystal Si are etched concurrently, forming contact trenches concurrently in the poly-silicon and the single crystal Si. In the single crystal Si, the covalent bonds of the single crystal Si are broken in the ion implanted regions, increasing the etching rate. As a result, the etching rate of the ion implanted regions of the single crystal Si may be brought close to the etching rate of the poly-silicon. Thus, the difference in the depths of the contact trenches formed concurrently in the poly-silicon and in the single crystal Si may be reduced. Further, the etching rate of the single crystal Si is increased, thereby reducing the etching time and improving productivity for the semiconductor device.

According to the embodiment, the poly-silicon is deposited, via the LOCOS film, on the semiconductor substrate containing single crystal Si and configures the gate polysilicon wiring layer. When the contact trenches are formed concurrently in the single crystal Si and the poly-silicon, even when the contact trench formed in the gate polysilicon wiring layer reaches the LOCOS film, as described above, the difference in the depths of the contact trenches formed concurrently may be reduced and thus, the etching amount of the LOCOS film is reduced. As a result, the LOCOS film may be left having a predetermined thickness ensuring insulation that may withstand the power supply voltage used in a circuit in which the semiconductor devices is mounted and the dielectric breakdown and breakdown voltage strength of the LOCOS film is increased. Thus, the reliability of the semiconductor device is improved.

Verification of the implantation depth d21 of the ion implantation 52 at step S5 in the method of manufacturing the semiconductor device according to the embodiment described above (refer to FIG. 4) was performed. FIG. 10 is a characteristic diagram depicting a relationship between acceleration voltage and range (Rp-standard deviation (1σ)) of boron ions. The ion species used for ion implantation was boron ions (B⁺), and the acceleration voltage was calculated based on the mass of the ion species. Further, regarding the boron ions (B⁺), the range (=implantation depth) in the single crystal Si was calculated as a function of the acceleration voltage of the ion implantation and is depicted in FIG. 10.

As depicted in FIG. 10, it was found that the range of ion implantation in single crystal Si increases almost linearly as the acceleration voltage of ion implantation increases. In the method of manufacturing the semiconductor device of the reference example, the p⁺⁺-type contact region 103 is formed by the ion implantation 122 applied to the semiconductor substrate 101 exposed at the bottom of the contact trench 101a and thus, as described above, the range of the ion implantation 122 (=the implantation depth d111) is the total sum (more than 600 Å) of the thickness of the silicide layer and the design thickness of the p⁺⁺-type contact region 103. Thus, based on the results depicted in FIG. 10, it is found that the acceleration voltage of the ion implantation 122 may to be set to about 30 keV.

On the other hand, in the method of manufacturing the semiconductor device according to the embodiment, the p⁺⁺-type contact regions 15 are formed by the ion implantation 52 to the semiconductor substrate 20 and thereafter, the p⁺⁺-type contact regions 15 are etched to the predetermined depth d1, thereby forming the contact trenches 20a. Thus, as described above, the range of the ion implantation 52 (=the implantation depth d21) is the total sum (more than 7600 Å) of the depth d1 of the contact trenches 20a, the thickness of the silicide layer, and the design thickness t10 of the p⁺⁺-type contact regions 15. Thus, based on the results depicted in FIG. 10, it was found that the acceleration voltage of the ion implantation 52 may be set to be about 375 keV.

As described, regarding the ion species used in the ion implantation 52 at step S5, the range of the ion implantation to the single crystal Si is calculated as a function of the acceleration voltage of the ion implantation in advance. As a result, the acceleration voltage of the ion implantation may be obtained, based on the range of the ion implantation calculated from the depth d1 of the contact trenches 20a, the thickness of the silicide layer, and the design thickness t10 of the p⁺⁺-type contact regions 15. In an instance in which n⁺⁺-type contact regions are formed instead of the p⁺⁺-type contact regions 15, regarding the n-type ion species as well, the range of the ion implantation to the single crystal Si may be calculated as a function of the acceleration voltage of the ion implantation.

Verification regarding the difference in the etching rate of the single crystal Si and the etching rate of poly-silicon was performed. FIG. 11 is a characteristics diagram schematically depicting a difference in the etching rates (=the etching amount/the etching time) of the single crystal Si and poly-silicon. As depicted in FIG. 11, experiments by the inventors confirmed that the etching amount increases almost linearly as the etching time increases for both single crystal Si and poly-silicon. The greater the slope of the line, the higher the etching rate and the easier the etching is. When the etching time is set according to the etching amount of the single crystal Si, it was found that the longer the etching time is, the greater the actual etching amount of the poly-silicon deviates from the target etching amount (=the etching amount of the single crystal Si) of the poly-silicon.

Further, from the results depicted in FIG. 11, the etching rate of single crystal Si is about 0.73 times the etching rate of poly-silicon and the etching rate of the poly-silicon is about 26% to 27% higher as compared to that of the single crystal Si. When the etching amount of the single crystal Si is set to 0.70 μm, the etching amount of the poly-silicon may be about 0.95 μm.

Verification regarding the etching rate of the single crystal Si during the etching at step S6 in the method of manufacturing the semiconductor device according to the embodiment described above (refer to FIG. 4) was performed.

A trench contact structure (hereinafter, the reference example) was formed in predetermined locations (the source contact portion and the gate contact portion) according to the method of manufacturing the semiconductor device of the reference example (refer to FIG. 12). In the reference example, in the process at step S105, a single crystal Si portion (the semiconductor substrate 101) and a poly-silicon portion (the gate polysilicon wiring layer 112) are etched concurrently, thereby forming the contact trenches 101a, 112a. As for the ion implantation 122 (corresponds to the process at step S107) in the reference example, the ion species was B⁺, the acceleration voltage was 30 keV, and the ion implantation 122 was performed after formation of the contact trenches 101a, 112a. The depth d101 of the contact trench 101a was 0.70 μm. The thickness of the gate polysilicon wiring layer 112 was 0.5 μm. The thickness of the LOCOS film 111 was 0.5 μm.

Based on the results of the verification (the etching rate of poly-silicon being 27% higher than the etching rate of single crystal Si), the etching rate of the LOCOS film 111 was also considered and the etching amount d103 of the LOCOS film 111 at the bottom of the contact trench 112a was estimated. The depth d102 of the contact trench 112a was about 0.80 μm and was about +0.10 μm deeper as compared to the depth d101 of the contact trench 101a. The etching amount d103 of the LOCOS film 111 at the bottom of the contact trench 112a may be about 0.30 μm.

A trench contact structure (hereinafter, first and second examples) was formed at predetermined locations (source contact portion and gate contact portion) according to the method of manufacturing the semiconductor device according to the embodiment. In the first and second examples, in the process at step S6, the single crystal Si portion (the p⁺⁺-type contact regions 15 formed by the ion implantation 52 at step S5) and the poly-silicon portion (the p⁺⁺-type dopant region 37 formed by the ion implantation 52 at step S5) are etched concurrently, thereby forming the contact trenches 20a, 32a. Here, the etching rate and the etching time of the single crystal Si portion may be obtained.

Ion implantation conditions of the ion implantation 52 in the first example included the ion species being B⁺, the acceleration voltage being 375 keV, and the dose amount being 3.00×10¹⁵ ions/cm². The depth d1 of the contact trenches 20a was 0.70 μm. The thickness t2 of the gate polysilicon wiring layer 32 was 0.5 μm. The thickness t1 of the LOCOS film 31 was 0.5 μm. Ion implantation conditions of the ion implantation 52 in the second example were the same as those of the first example excluding the ion species, which was BF₂⁺ and the acceleration voltage, which was 3250 keV.

In the first example, the etching rate of the single crystal Si portion (the p⁺⁺-type contact regions 15) is greater than the etching rate of the single crystal Si portion in the reference example. Based on these experimental results, the etching rate of the poly-silicon in the first example was assumed to be about the same as the etching rate of the poly-silicon in the reference example and the etching amount d3 of the LOCOS film 31 at the bottom of the contact trench 32a in the first example was estimated. Even when the etching time of the single crystal Si portion is set to a longest value (time) within an allowable error range due to variation of the etching rate, the etching time is shorter than that in the reference example and the depth d2 of the contact trench 32a in the first example is about 0.70 μm, which is shallower than the depth d102 of the contact trench 112a in the reference example. The difference in the respective depths of the contact trench 32a and the contact trenches 20a in the first example (=d2-d1) is about ±0.00 μm and the etching amount d3 of the LOCOS film 31 in the first example is reduced as compared to the etching amount d103 of the LOCOS film 111 in the reference example. The etching amount d3 of the LOCOS film 31 at the bottom of the contact trench 32a may be about 0.20 μm.

In the second example, the etching rate of the single crystal Si portion (the p⁺⁺-type contact regions 15) may be greater than the etching rate of the single crystal Si portion in the first example. In other words, the second example shortens the etching time of the etching process at step S6 as compared to the first example. For example, the etching rate of the single crystal Si portion may be suitably set according to the ion species of the ion implantation 52 at step S5. The etching rate of poly-silicon in the second example was assumed to be about the same as the etching rate of poly-silicon in the reference example and the etching amount d3 of the LOCOS film 31 at the bottom of the contact trench 32a in the second example was estimated. Even when the etching time of the single crystal Si portion was set the longest value within the allowable error range due to variation of the etching rate, the etching time was shorter than that in the first example, whereby the depth d2 of the contact trench 32a in the second example was shallower than the depth d2 of the contact trench 32a in the first example (i.e., d2-d1<0.00 μm). Thus, in the second example, the etching amount d3 of the LOCOS film 31 at the bottom of the contact trench 32a was also reduced as compared to the first example.

As described, in the first and second examples, the etching rate of the single crystal Si portion is increased, whereby the etching rate of the single crystal Si portion approaches the etching rate of poly-silicon. Thus, when the single crystal Si portion (the p⁺⁺-type contact regions 15) and the poly-silicon portion (the p⁺⁺-type dopant region 37) are concurrently etched, thereby forming the contact trenches 20a, 32a, the depth d1 of the contact trenches 20a (=the etching amount of the single crystal Si portion) may be maintained at 0.70 μm while the depth d2 of the contact trench 32a may be made shallower as compared to that of the reference example. Thus, the etching amount d3 of the LOCOS film 31 is smaller as compared to that of the reference example and when the thickness t1 of the LOCOS film 31 is about 0.5 μm, the thickness of the LOCOS film 31 between the bottom of the contact trench 32a and the front surface of the semiconductor substrate 20 may be assuredly left having the predetermined thickness. For example, the etching amount d3 of the LOCOS film 31 is estimated to not be more than 0.30 μm.

The etching amount d3 of the LOCOS film 31 may be estimated by the following method. First, the etching time for forming the contact trenches 20a of the predetermined depth d1 in the single crystal Si portion is estimated from the etching rate of the single crystal Si portion (portion of the semiconductor substrate 20 amorphized by the ion implantation 52). Next, the etching time for etching, in the depth direction, the gate polysilicon wiring layer 32 of the predetermined thickness t2 and constituting the gate contact portion (i.e., the etching amount of the gate polysilicon wiring layer 32=the thickness t2 of the gate polysilicon wiring layer 32) is estimated from the etching rate of the poly-silicon portion (portion of the gate polysilicon wiring layer 32 subjected to the ion implantation 52). The sequence in which the processes of estimating the etching time of the single crystal Si portion and estimating the etching time of the poly-silicon portion are performed may be interchanged.

Next, as described above, the etching time of the LOCOS film 31 is estimated from the obtained etching time of the single crystal Si portion and the obtained etching time of the poly-silicon portion. For example, the etching time of the LOCOS film 31 is calculated by subtracting the etching time of the polysilicon portion from the etching time of the single crystal Si portion. Next, from the etching time of the LOCOS film 31 and the etching rate of the LOCOS film 31 obtained as described, the etching amount d3 of the LOCOS film is estimated. The respective etching rates of the single crystal Si portion, the poly-silicon portion, and the LOCOS film 31 may all be obtained by experiment, and the remaining etching rate may be calculated from the experimentally obtained etching rates of the single crystal Si portion, the polysilicon portion, and the LOCOS film 31, and the respective etching selectivity ratios thereof.

In the foregoing, the present disclosure is not limited to the embodiments described above and various modifications within a range not departing from the spirit of the disclosure are possible. For example, when a semiconductor substrate has the single crystal Si region and the polycrystalline Si (poly-silicon) region and when trenches are concurrently formed in the single crystal Si region and the polycrystalline Si and it is desirable to reduce the difference in the etching amounts between the trenches, the present disclosure is applicable. Further, a planar gate structure may be adopted instead of the trench gate structure, and an insulated gate bipolar transistor (IGBT) may be adopted instead of the MOSFET. Further, a normal drift layer configured by only an n⁻-type region may be adopted instead of the drift layer having a SJ structure.

The method of manufacturing the semiconductor device according to the present disclosure achieves an effect in that reliability of the semiconductor device may be improved.

As described above, the method of manufacturing the semiconductor device according to the present disclosure is useful in an instance in which portions containing differing materials are to be concurrently processed by etching and the difference in the etching amounts between the portions is to be reduced, and the method is particularly useful for semiconductor devices having a trench contact structure as a contact between a surface electrode and a predetermined portion.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a semiconductor device, the method comprising:
preparing a semiconductor substrate having a main surface, a single crystal silicon region formed in the semiconductor substrate, and a polycrystalline silicon region formed on the semiconductor substrate at the main surface;
as a first process, forming an interlayer insulating film covering the single crystal silicon region and the polycrystalline silicon region;
as a second process, forming in the interlayer insulating film, a plurality of first contact holes exposing the single crystal silicon region and a second contact hole exposing the polycrystalline silicon region;
as a third process, performing an ion implantation of a dopant in the single crystal silicon region, at portions thereof exposed by the plurality of first contact holes;
as a fourth process, using the interlayer insulating film as a mask and etching the single crystal silicon region and the polycrystalline silicon region, thereby concurrently forming a plurality of first contact trenches respectively continuous with the plurality of first contact holes and a second contact trench continuous with the second contact hole;
as a fifth process, forming a first electrode electrically connected to the single crystal silicon region at an inner wall of each of the plurality of first contact trenches; and
as a sixth process, forming a second electrode electrically connected to the polycrystalline silicon region at an inner wall of the second contact trench.

2. The method of manufacturing the semiconductor device according to claim 1, wherein
in the third process, the ion implantation forms a plurality of first regions in the single crystal silicon region to break covalent bonds of single crystal silicon therein; and
the fourth process further includes etching the plurality of first regions, thereby forming the plurality of first contact trenches.

3. The method of manufacturing the semiconductor device according to claim 2, wherein
the third process further includes forming a second region in the polycrystalline silicon region concurrently with the plurality of first regions, by the ion implantation, and
the fourth process further includes etching the second region, thereby forming the second contact trench.

4. The method of manufacturing the semiconductor device according to claim 1, wherein
the semiconductor substrate is formed completely by the single crystal silicon region;
the semiconductor substrate further has:
a first device region in which the plurality of first contact trenches are formed, and
a second device region apart from the first device region, and
the polycrystalline silicon region is formed in the second device region, via an insulating layer.

5. The method of manufacturing the semiconductor device according to claim 4, wherein the first process further includes performing a thermal oxidation, thereby forming the insulating layer.

6. The method of manufacturing the semiconductor device according to claim 4, wherein the first process further includes forming a device structure in the first device region.

7. The method of manufacturing the semiconductor device according to claim 1, wherein
the dopant contains boron, and
in the ion implantation, monovalent or divalent boron ions are implanted.

8. The method of manufacturing the semiconductor device according to claim 1, wherein the third process further includes setting an acceleration voltage of the ion implantation so that a peak of a concentration of the dopant occurs at a depth in a range of 0.40 μm to 0.90 μm from an ion-implanted surface of the ion implantation.
